(19) United States
(12) Patent Application Publication
(10) Pub. No.: US 2007/0082462 A1
(43) Pub. Date: Apr. 12, 2007

(54) Wafer having indicator for first die and method of attaching die of the wafer

(75) Inventors: Young-dae Kim, Seoul (KR); Soon-kwyon Jun, Yongin-si (KR); Hyun-soo Park, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/542,781

(22) Filed: Oct. 4, 2006

(30) Foreign Application Priority Data
Oct. 7, 2005 (KR) 10-2005-0094509

(51) Int. Cl. H01L 21/30; H01L 21/46; H01L 21/66; G01R 31/26

(52) U.S. Cl. 438/458; 438/14

(57) ABSTRACT

Provided are a wafer having an indicator for a first die and a method of attaching a die of the wafer. The wafer includes an indicator formed on a back surface at a position corresponding to a position of a first die on a front surface, for indicating the position of the first die. The method of attaching the die of the wafer includes forming an indicator for a first die, comparing positions of the indicator and the first die, and attaching the die of the wafer. In forming the indicator, the indicator is formed on a back surface of the wafer for indicating the position of the first die. In comparing the positions, the position of the first die formed on a front surface of the wafer is compared with the position of the indicator formed on the back surface of the wafer. If a position error between the positions of the first die and the indicator is smaller than a reference value, the attaching of the die of the wafer performed. Therefore, the error rate of the die attaching process can be decreased by using the wafer and the method of attaching the die of the wafer since the wafer includes the indicator giving information on the first die for distinguish the position of the first die.

### CROSS-REFERENCE TO RELATED PATENT APPLICATION

This application claims the benefit of Korean Patent Application No. 10-2005-0094509, filed on Oct. 7, 2005, in the Korean Intellectual Property Office, the contents of which are incorporated herein in their entirety by reference.

### BACKGROUND OF THE INVENTION

1. Field of the Invention

The present invention relates to a wafer and a method of attaching a die of the wafer, and more particularly, to a wafer having an indicator giving information on the position of a first die and a method of attaching a die of the wafer according to the position information of the first die.

2. Description of the Related Art

Recent wafers are usually processed by inkless and full-shot processes.

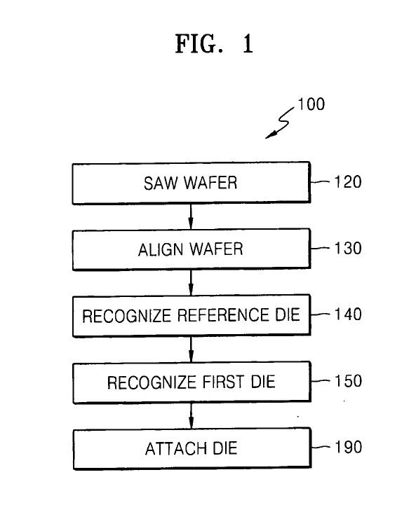

FIG. 1 is a flowchart showing a conventional method of attaching a wafer die.

Referring to FIG. 1, the conventional method includes wafer sawing 120, wafer aligning 130, reference die recognizing 140, first die recognizing 150, and die attaching 190.

In the first die recognizing 150, a CCD camera of a die attaching device recognizes the position of a first die. In the die attaching 190, the die attaching device performs die attaching by using the position information of the first die.

However, if the conventional method is performed using the inkless and full shot process, it is difficult to precisely detect the position of the first die using the CCD camera in the first die recognizing 150 since the CCD camera is not sufficiently precise.

Further, if the position of the first die is not precisely detected in the first die recognizing 150, the die attaching 190 is not precisely performed.

### SUMMARY OF THE INVENTION

The present invention provides a wafer having an indicator giving information on the position of a first die.

The present invention also provides a method of attaching a die of a wafer by precisely recognizing the position of the first die.

According to an aspect of the present invention, there is provided a wafer including an indicator formed on a back surface at a position corresponding to a position of a first die on a front surface, for indicating the position of the first die.

The indicator may be formed by etching the back surface of the wafer, and may have a size detectable using a sensor of a die attaching device.

According to another aspect of the present invention, there is provided a method of attaching a die of a wafer, the method including: forming an indicator on a back surface of the wafer for indicating a position of a first die; comparing the position of the first die formed on a front surface of the wafer with a position of the indicator formed on the back surface of the wafer; and if a position error between the positions of the first die and the indicator is smaller than a reference value, attaching the die of the wafer.

The method may further include: if the position error between the positions of the first die and the indicator is not smaller than the reference value, recognizing the position of the first die again and repeating the comparing using the re-recognized position of the first die.

The method may further include recognizing the position of the indicator formed on the back surface of the wafer, wherein the comparing is performed using the recognized position of the indicator.

The method may further include recognizing the position of the first die. In this case, if the position error between the positions of the first die and the indicator is not smaller than the reference value, the recognizing of the position of the first die may be performed again and the comparing may be performed again using the re-recognized position of the first die.

In one embodiment, forming the indicator is performed by etching the back surface of the wafer. In one embodiment, forming the indicator is performed by etching the back surface of the wafer using a laser.

According to a further another aspect of the present invention, there is provided a wafer including a first die selected from a plurality of dice formed by one shot in photolithography, the first die including a symbol indicating the first die.

In one embodiment, the symbol is formed by etching a front surface of the wafer. In one embodiment, the symbol has a size detectable using a sensor of a die attaching device.

The wafer may include a plurality of dice formed by one shot in photolithography, the respective dice including symbols for distinguishing the dice from each other.

In one embodiment, the symbols are formed by etching a front surface of the wafer. In one embodiment, the symbols have a size detectable using a sensor of a die attaching device.

According to a still further another aspect of the present invention, there is provided a method of attaching a die of a wafer, the method including: forming symbols respectively on a plurality of dice formed by one shot in photolithography, to distinguish the dice from each other; checking a symbol of a first die of the dice; and if the checked symbol is consistent with a correct symbol of the first die, attaching the die of the wafer.

In one embodiment, the method further comprises, if the checked symbol is not consistent with the correct symbol of the first die, recognizing the first die again and repeating the checking using a symbol of the re-recognized first die.

In one embodiment, the method further comprises recognizing a position of the first die.

In one embodiment, if the checked symbol is not consistent with the correct symbol of the first die, the recognizing of the position of the first die is performed again and the checking is performed again.

In one embodiment, the method further comprises, if the checked symbol is not consistent with the correct symbol of the first die, recognizing and checking symbols of dice surrounding the recognized first die. If one of the symbols of the surrounding dice is consistent with the correct symbol of the first die, the attaching of the die is performed, and if all of the symbols of the surrounding dice are not consistent with the correct symbol of the first die, the recognizing of the position of the first die is performed again.

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. FIG. 1 is a flowchart showing a conventional method of attaching a wafer die.

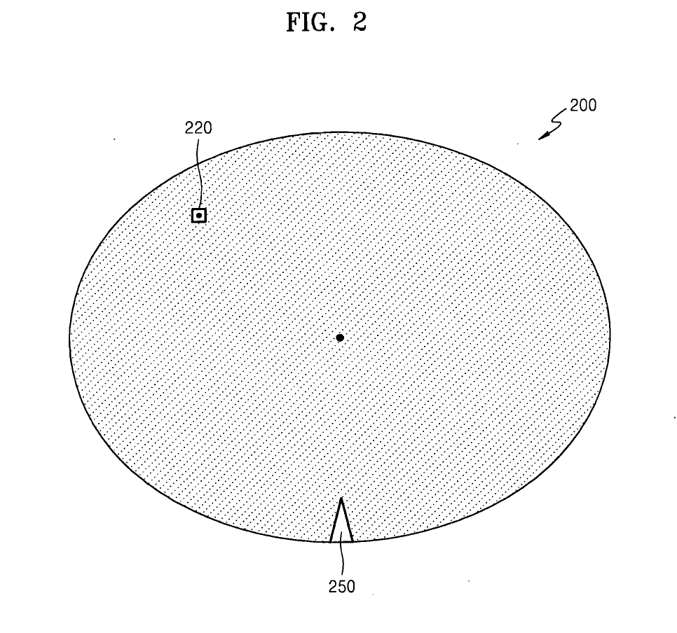

FIG. 2 shows a back surface of a wafer having an indicator giving information regarding the position of a first die of the wafer according to a first embodiment of the present invention.

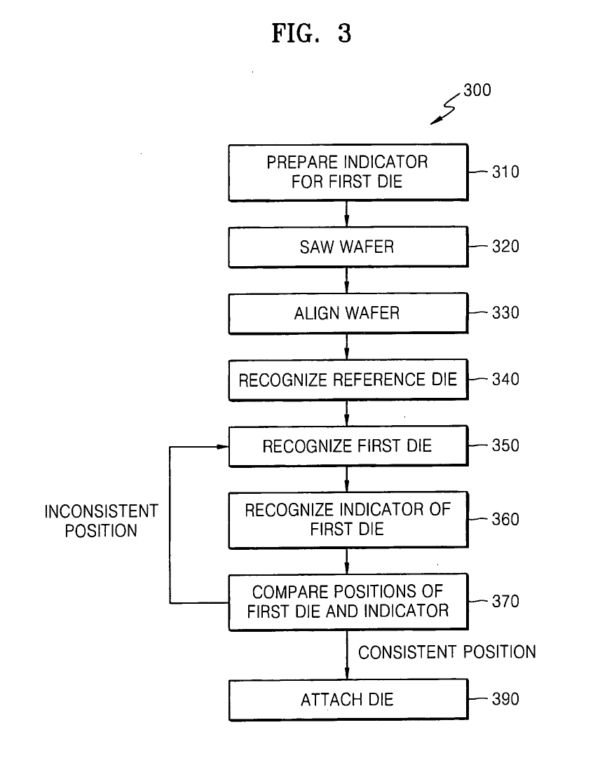

FIG. 3 is a flowchart showing a method of attaching a die of the wafer depicted in FIG. 2.

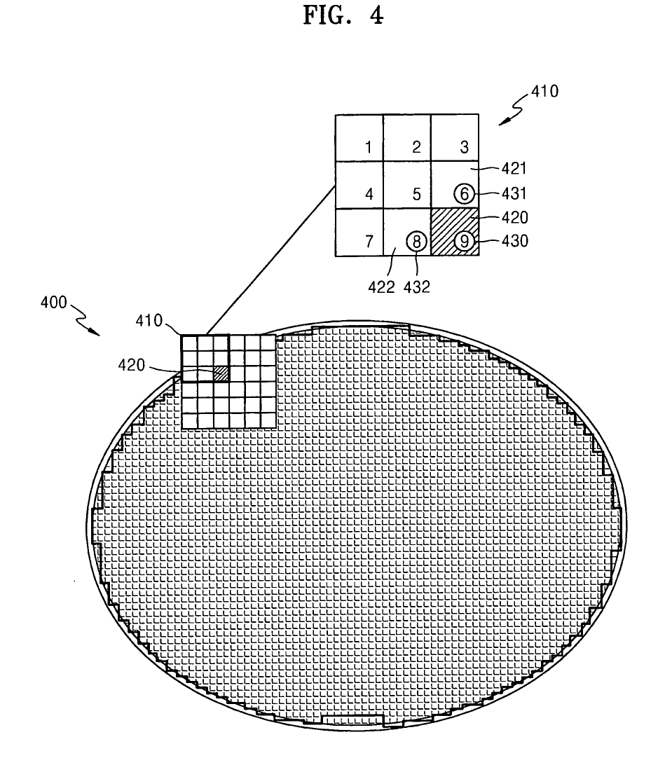

FIG. 4 shows a front surface of a wafer having an indicator giving information regarding the position of a first die of the wafer according to a second embodiment of the present invention.

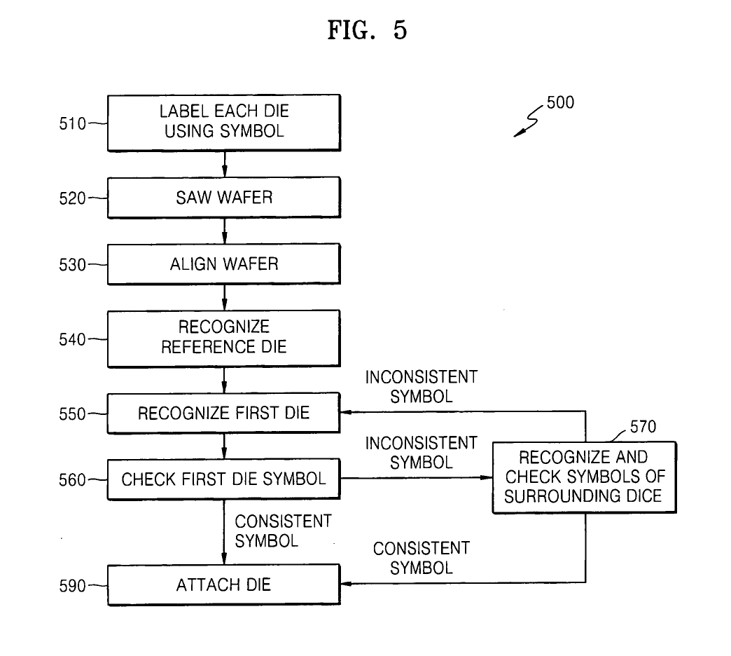

FIG. 5 is a flowchart showing a method of attaching a die of the wafer depicted in FIG. 4.

### DETAILED DESCRIPTION OF THE INVENTION

FIG. 2 shows a back surface of a wafer having an indicator giving information regarding the position of a first die of the wafer according to a first embodiment of the present invention.

The wafer according to the first embodiment of the present invention includes an indicator 220 on a back surface 200 for giving information on the position of a first die of the wafer. The indicator 220 is formed on the back surface 200 of the wafer at a position corresponding to the position of the first die on a front surface of the wafer.

The first die is located on the front surface of the wafer. The indicator 220 is located on the back surface 200 of the wafer at a position corresponding to the position of the first die on the front surface of the wafer to indicate the position of the first die. The indicator 220 may be located just back of the first die or at a position spaced a predetermined distance from the first die.

Further, the indicator 220 may be formed by etching the back surface 200 of the wafer. That is, the indicator 220 may be formed into a concaved shape by etching silicon of the back surface 200. If the indicator 220 is formed into a convex shape, undesired morphology can be introduced in the wafer to cause cracks of the wafer. Therefore, the indicator 220 may be formed into the concave shape.

Furthermore, etching the wafer may be performed using a laser.

The indicator 220 may be sized such that the indicator 220 can be detected using a sensor of a die attaching device. In this case, die attaching process can be rapidly performed for the die of the wafer since the die attaching device can easily detect the indicator 220 using its sensor. Further, since the indicator 220 can be detected using the existing die attaching device, an additional device is not required.

FIG. 3 is a flowchart showing a method 300 of attaching a die of the wafer depicted in FIG. 2.

Referring to FIG. 3, the method 300 includes preparing an indicator for a first die (operation 310), comparing positions of the first die and the indicator (operation 370), and attaching a die (operation 390).

In operation 310, the indicator is formed on a back surface of a wafer to give information on the position of the first die. Operation 310 corresponds to forming the indicator 220 on the back surface 200 of the wafer depicted in FIG. 2. Therefore, operation 310 may be obvious to those of skill in the related art from the description set forth above, and thus more detailed description of operation 310 will be omitted.

In operation 370, the position of the first die on the front surface of the wafer is compared with the position of the indicator on the back surface of the wafer.

If a position error between the positions of the first die and the indicator is smaller than a reference value, operation 390 starts.

On the contrary, if the position error between the positions of the first die and the indicator is larger than the reference value, the position of the first die on the front surface of the wafer is recognized again. Then, operation 370 is performed again using the re-recognized position of the first die.

The method 300 may further include recognizing the indicator giving information on the first die (operation 360). In operation 360, the position of the indicator is recognized using a sensor. The sensor of the die attaching device or a separate sensor may be used for operation 360.

The method 300 may further include recognizing the first die (operation 350). In operation 350, the position of the first die is recognized from the front surface of the wafer.

The method 300 of attaching the die of the wafer depicted in FIG. 2 will now be further described in detail with reference to FIG. 3.

In operation 350, the position of the first die formed on the front surface of the wafer is recognized.

Next, operation 360 is performed to recognize the position of the indicator, which is formed on the back surface of the wafer to give information on the position of the first die.

Next, operation 370 is performed to compare the position of the first die recognized in operation 350 with the position of the indicator recognized in operation 360.

If a position error between the positions of the first die and the indicator is smaller than a reference value, it is determined that the position of the first die recognized in operation 350 is correct. Therefore, operation 390 is performed to attach a die of the wafer using the position information of the first die.

On the contrary, if the position error between the positions of the first die and the indicator is larger than the reference value, operation 390 is not performed. Instead, operations 350, 360, and 370 are repeated again. In more detail, the position of the first die may not be precisely recognized due to the resolution of a CCD camera of the die attaching device. In this case, operations 350, 360, and 370 are repeated until the position error between the positions of the first die and the indicator becomes smaller than the reference value.

Here, the reference value is properly selected such that operation 390 can be performed without errors if the position error between the positions of the first die and the indicator recognized in operations 350 and 360 is smaller than the reference value.

FIG. 4 shows a front surface of a wafer 400 having an indicator giving information regarding the position of a first die of the wafer according to a second embodiment of the present invention.

With reference to FIG. 4, a first die 420 of the wafer 400 according to the second embodiment of the present invention includes a symbol 430 as an indicator. In more detail, in photolithography for the wafer 400, a single shot 410 includes a plurality of dice 420, 421, and 422. Among the plurality of dice 420, 421, and 422, the first die 420 includes the symbol 430 to indicate itself. The numeral “9” is used for the symbol 430 in FIG. 4 as an example. Other numbers, characters, and geometrical figures can be used for the symbol 430 to indicate the first die 420.

Referring again to FIG. 4, the dice 420, 421, and 422 included in the shot 410 of the wafer 400 may be respectively provided with symbols 430, 431, 432 to distinguish the dice 420, 421, and 422 from other dice in the shot 410. In FIG. 4, dice of the shot 410 are respectively provided with 1, 2, 3, 4, 5, 6, 7, 8, 9 numbers as exemplary symbols. However, other numbers, characters, and geometric figures can be used for the symbols to indicating the respective dice.

The symbols 430, 431, and 432 may be marked on the front surface of the wafer 400 by etching the front surface of the wafer 400. That is, the symbols 430, 431, and 432 may be formed into a concave shape by etching the silicon of the front surface of the wafer 400. Further, the symbols 430, 431, and 432 may be recognized using a sensor of a die attaching device. Furthermore, a laser may be used for etching the front surface of the wafer to form the symbols 430, 431, and 432.

FIG. 5 is a flowchart showing a method 500 of attaching a die of the wafer depicted in FIG. 4.

Referring to FIG. 5, the method 500 includes labeling die using a symbol (operation 510), checking a first die symbol (operation 560), and attaching a die (operation 590).

In operation 510, symbols are formed on respective dice included in one shot made by photolithography process to distinguish the dice from each other. Operation 510 corresponds to forming the symbols 430, 431, and 432 on the dice of the wafer 400 depicted in FIG. 4. Therefore, operation 510 may be obvious to those of skill in the related art from the description set forth above, and thus more detailed description of operation 510 will be omitted.

The method 500 may further include recognizing a first die (operation 550). In operation 550, the position of the first die is recognized using a sensor. The sensor may be the sensor of the die attaching device or a separate sensor.

In operation 560, it is determined whether the symbol of the recognized first die is consistent with a correct symbol. Here, the correct symbol is the symbol 430 formed on the first die in operation 510.

If the symbol of the recognized first die is consistent with the correct symbol, operation 590 starts.

On the contrary, if the symbol of the recognized first die is not consistent with the correct symbol, the first die is recognized again. Then, operation 560 is repeated again. That is, it is determined again whether the symbol of the re-recognized first die is consistent with the correct symbol.

If it is determined that the symbol of the recognized first die is consistent with the correct symbol in operation 560, the position of the first die recognized in operation 550 is correct. Therefore, operation 590 is performed using the position information of the first die.

On the contrary, if it is determined that the symbol of the recognized first die is not consistent with the correct symbol in operation 560, operation 590 is not performed. Instead, operations 550 and 560 are repeated again. That is, operations 550 and 560 are repeated until the symbol of the re-recognized first die is consistent with the correct symbol.

Referring again to FIG. 5, the method 500 may further include recognizing and checking surrounding dice symbols (operation 570). In operation 570, symbols of dice surrounding the first die recognized in operation 550 are recognized, and it is determined whether one of the symbols of the surrounding dice is consistent with the correct symbol of the first die.

If it is determined that the symbol of the recognized first die is not consistent with the correct symbol in operation 560, operation 570 is performed before operation 550 and 560 are repeated.

In operation 570, one of the symbols of the surrounding dice is consistent with the correct symbol of the first die, the die having the consistent symbol is determined as the first die and operation 590 is performed accordingly. On the contrary, in operation 570, if the symbols of the surrounding dice are not consistent with the correct symbol of the first die, operation 550 and 560 are repeated.

As described above, according to the present invention, the error rate of the die attaching process can be decreased by using the wafer and the method of attaching the die of the wafer since the wafer includes the indicator giving information on the first die for distinguish the position of the first die.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wafer comprising an indicator formed on a back surface at a position corresponding to a position of a first die on a front surface, for indicating the position of the first die.

2. The wafer of claim 1, wherein the indicator is formed by etching the back surface of the wafer.

3. The wafer of claim 1, wherein the indicator has a size detectable using a sensor of a die attaching device.

4. A method of attaching a die of a wafer, comprising:
forming an indicator on a back surface of the wafer for indicating a position of a first die;
comparing the position of the first die formed on a front surface of the wafer with a position of the indicator formed on the back surface of the wafer; and
if a position error between the positions of the first die and the indicator is smaller than a reference value, attaching the die of the wafer.

5. The method of claim 4, further comprising:
if the position error between the positions of the first die and the indicator is not smaller than the reference value, recognizing the position of the first die again and repeating the comparing using the re-recognized position of the first die.

6. The method of claim 4, further comprising recognizing the position of the indicator formed on the back surface of the wafer,.wherein the comparing is performed using the recognized position of the indicator.

7. The method of claim 6, further comprising recognizing the position of the first die.

8. The method of claim 7, wherein if the position error between the positions of the first die and the indicator is not smaller than the reference value, the recognizing of the position of the first die is performed again and the comparing is performed again using the re-recognized position of the first die.

9. The method of claim 4, wherein the forming of the indicator is performed by etching the back surface of the wafer.

10. The method of claim 9, wherein the forming of the indicator is performed by etching the back surface of the wafer using a laser.

11. A wafer comprising a first die selected from a plurality of dice formed by one shot in photolithography, the first die including a symbol indicating the first die.

12. The wafer of claim 11, wherein the symbol is formed by etching a front surface of the wafer.

13. The wafer of claim 11, wherein the symbol has a size detectable using a sensor of a die attaching device.

14. A wafer comprising a plurality of dice formed by one shot in photolithography, the respective dice including symbols for distinguishing the dice from each other.

15. The wafer of claim 14, wherein the symbols are formed by etching a front surface of the wafer.

16. The wafer of claim 14, wherein the symbols have a size detectable using a sensor of a die attaching device.

17. A method of attaching a die of a wafer, comprising:
forming symbols respectively on a plurality of dice formed by one shot in photolithography, to distinguish the dice from each other;
checking a symbol of a first die of the dice; and
if the checked symbol is consistent with a correct symbol of the first die, attaching the die of the wafer.

18. The method of claim 17, further comprising:
if the checked symbol is not consistent with the correct symbol of the first die, recognizing the first die again and repeating the checking using a symbol of the re-recognized first die.

19. The method of claim 17, further comprising recognizing a position of the first die.

20. The method of claim 19, wherein if the checked symbol is not consistent with the correct symbol of the first die, the recognizing of the position of the first die is performed again and the checking is performed again.

21. The method of claim 20, further comprising:
if the checked symbol is not consistent with the correct symbol of the first die, recognizing and checking symbols of dice surrounding the recognized first die,
wherein if one of the symbols of the surrounding dice is consistent with the correct symbol of the first die, the attaching of the die is performed, and if all of the symbols of the surrounding dice are not consistent with the correct symbol of the first die, the recognizing of the position of the first die is performed again.
